(19) United States
(12) Patent Application Publication
(10) Pub. No.: US 2011/0001247 A1
(43) Pub. Date: Jan. 6, 2011

(54) SEMICONDUCTOR DEVICE MANUFACTURING METHOD

(75) Inventor: Hiroyasu JOBETTO, Hachioji-shi (JP)

Correspondence Address: HOLTZ, HOLTZ, GOODMAN & CHICK PC, 220 Fifth Avenue, 16TH Floor, NEW YORK, NY, 10001-7708, US

(73) Assignee: Casio Computer Co., Ltd., Tokyo (JP)

(21) Appl. No.: 12/827,651

(22) Filed: Jun. 30, 2010

(30) Foreign Application Priority Data
Jul. 1, 2009 (JP) 2009-156951
May 14, 2010 (JP) 2010-111639

(51) Int. Cl. H01L 23/48; H01L 21/768; H01L 21/50

(52) U.S. Cl. 257/774; 438/675; 438/122; 257/E21.577; 257/E23.01; 257/E21.499

(57) ABSTRACT

A semiconductor device manufacturing method comprises bonding a semiconductor element onto one surface of a first protective film via an adhesive layer, an electrode being formed in the semiconductor element, the first protective film being disposed on a first base material and including a first via hole, removing the first base material from the first protective film, applying first laser light to the adhesive layer through the first via hole to form a second via hole in the adhesive layer so that the electrode is exposed through the adhesive layer, and forming a metal layer in the second via hole to connect the metal layer to the electrode.

### CROSS-REFERENCE TO RELATED APPLICATIONS

This application is based upon and claims the benefit of priority from prior Japanese Patent Applications No. 2009-156951, filed Jul. 1, 2009; and No. 2010-111639, filed May 14; 2010, the entire contents of both of which are incorporated herein by reference.

### BACKGROUND OF THE INVENTION

1. Field of the Invention

The present invention relates to a semiconductor device manufacturing method.

2. Description of the Related Art

A conventional semiconductor device has been described in, for example, Jpn. Pat. Appln. KOKAI Publication No. 2008-42063. In this semiconductor device, a semiconductor element is mounted on a substrate. A sealing member is molded onto the substrate. The semiconductor element is packaged by the sealing member. A via hole is formed in the substrate under the semiconductor element. The via hole is filled with a conductor. An electrode of the semiconductor element is electrically connected to an external electrode by the conductor.

### BRIEF SUMMARY OF THE INVENTION

In the meantime, as the semiconductor element is mounted on the substrate, the whole semiconductor device is increased in thickness due to the thickness of the substrate. Accordingly, attempts have been made to mount the semiconductor element on an insulating film. A single insulating film is apt to deform. Therefore, an insulating film is supported on a support base material, on which a semiconductor element is mounted. Further, a sealing member is molded onto the insulating film, and then the base material is removed by, for example, etching. Then, laser light is applied to the insulating film to form a via hole in the insulating film. The via hole penetrates up to an electrode of the semiconductor element. Then, conductor is provided in the via hole, and a wiring line is patterned on the surface of the insulating film.

However, the semiconductor element is thermally damaged when the via hole is formed in the insulating film by the laser light. If the intensity of the laser light is low to inhibit the semiconductor element from being thermally damaged, the via hole cannot be formed in the insulating film.

It is therefore an object of the invention to prevent the semiconductor element from being thermally damaged by the laser light.

A semiconductor device manufacturing method according to the present invention comprises:

bonding a semiconductor element onto one surface of a first protective film via an adhesive layer, an electrode being formed in the semiconductor element, the first protective film being disposed on a first base material and including a first via hole;

removing the first base material from the first protective film;

applying first laser light to the adhesive layer through the first via hole to form a second via hole in the adhesive layer so that the electrode is exposed through the adhesive layer; and

forming a metal layer in the second via hole to connect the metal layer to the electrode.

Preferably, the diameter of the first laser light is greater than the diameter of the first via hole, and the second via hole is formed using the first protective film as a mask.

Preferably, the first protective film contains a fiber-reinforced resin.

Preferably, the first protective film is provided with at least one or more metal mask layers, and the metal mask layer is removed after the second via hole is formed.

Preferably, the first laser light is ultraviolet laser light.

Preferably, the first via hole is formed by applying second laser light to the first protective film, the second laser light being hi_{g}her in intensity than the first laser light.

Preferably, the first via hole is formed by applying carbon dioxide laser light to the first protective film.

Preferably, the metal layer is formed continuously from the second via hole onto the first protective film, and

the metal layer is patterned to form a wiring line connected to the electrode.

Preferably, the semiconductor element bonded to the first protective film is sealed with a sealing layer.

Preferably, the sealing layer is held between the semiconductor element bonded to the one surface of the first protective film and a second protective film disposed on a second base material, and the sealing layer is pressurized both from the side of the first base material and from the side of the second base material.

Preferably, the second protective film is made of the same material as the first protective film.

Preferably, an upper ground layer is formed on the second protective film.

Preferably, a lower ground layer is formed on the one surface of the first protective film around the semiconductor element.

Preferably, a heat sink is formed on the second protective film.

Preferably, a first metal layer containing a material different from that of the first base material is provided between the first protective film and the first base material,

carbon dioxide laser light is applied to the first protective film to form the first via hole in the first protective film, and

the first metal layer is etched through the first via hole using the first protective film as a mask.

Preferably, a second metal layer containing a material different from that of the first metal layer is provided between the first protective film and the first metal layer, and

the second metal layer is etched through the first via hole using the first protective film as a mask.

According to the present invention, a semiconductor element can be manufactured in a satisfactory manner.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view of a semiconductor device according to a first embodiment of the present invention;

FIG. 2 is a sectional view showing, by way of example, a semiconductor construct to be packaged;

FIG. 3 is a sectional view showing, by way of example, the semiconductor construct to be packaged;

FIG. 4 is a sectional view showing, by way of example, the semiconductor construct to be packaged;

FIG. 5 is a sectional view of a raw material in an initial step of a method of manufacturing the semiconductor device shown in FIG. 1;

FIG. 6 is a sectional view of a step following FIG. 5;

FIG. 7 is a sectional view of a step following FIG. 6;

FIG. 8 is a sectional view of a step following FIG. 7;

FIG. 9 is a sectional view of a step following FIG. 8;

FIG. 10 is a sectional view of a step following FIG. 9;

FIG. 11 is a sectional view of a step following FIG. 10;

FIG. 12 is a sectional view of a step following FIG. 11;

FIG. 13 is a sectional view of a step following FIG. 12;

FIG. 14 is a sectional view of a step following FIG. 13;

FIG. 15 is a sectional view of a step following FIG. 14;

FIG. 16 is a sectional view of a semiconductor device according to a second embodiment of the present invention;

FIG. 17 is a sectional view of a semiconductor device according to a third embodiment of the present invention;

FIG. 18 is a sectional view of a semiconductor device according to a fourth embodiment of the present invention;

FIG. 19 is a sectional view of one step of a method of manufacturing the semiconductor device shown in FIG. 18;

FIG. 20 is a sectional view of a semiconductor device according to a fifth embodiment of the present invention;

FIG. 21 is a sectional view of one step of a method of manufacturing the semiconductor device shown in FIG. 20;

FIG. 22 is a sectional view of a raw material in an initial step of a method of manufacturing a semiconductor device according to a sixth embodiment of the present invention;

FIG. 23 is a sectional view of a step following FIG. 22;

FIG. 24 is a sectional view of a step following FIG. 23;

FIG. 25 is a sectional view of a step following FIG. 24;

FIG. 26 is a sectional view of a step following FIG. 25;

FIG. 27 is a sectional view of a step following FIG. 26;

FIG. 28 is a sectional view of a step following FIG. 27;

FIG. 29 is a sectional view of a step following FIG. 28;

FIG. 30 is a sectional view of a step following FIG. 29;

FIG. 31 is a sectional view of one step of a method of manufacturing a semiconductor device according to a seventh embodiment of the present invention;

FIG. 32 is a sectional view of one step of a method of manufacturing a semiconductor device according to an eighth embodiment of the present invention; and

FIG. 33 is a sectional view of a step following FIG. 32.

### DETAILED DESCRIPTION OF THE INVENTION

Preferred embodiments of the present invention will be described below with reference to the drawings. Although various limitations technically preferred in carrying out the invention are put on the embodiments described below, these limitations do not restrict the scope of the invention to the following embodiments and examples shown in the drawings.

### First Embodiment

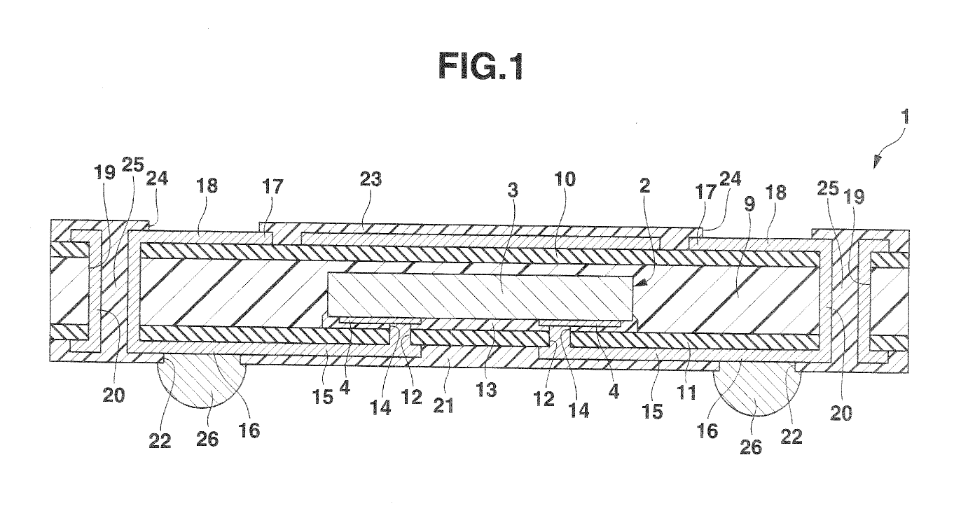

FIG. 1 is a sectional view of a semiconductor device 1.

This semiconductor device 1 has a packaged semiconductor construct 2. The semiconductor construct 2 includes a semiconductor element 3 having an integrated circuit such as a transistor, and a plurality of electrodes 4. The semiconductor element 3 has the integrated circuit provided on the lower surface of a semiconductor substrate such as a silicon substrate. The electrodes 4 are provided on the lower surface of the semiconductor element 3. The electrodes 4 contain Cu. The electrodes 4 may be parts of a wiring line. A plurality of unshown connection pads are arranged on four peripheral edges of the lower surface of the semiconductor element 3. The connection pads are connected to the integrated circuit formed in the semiconductor element 3.

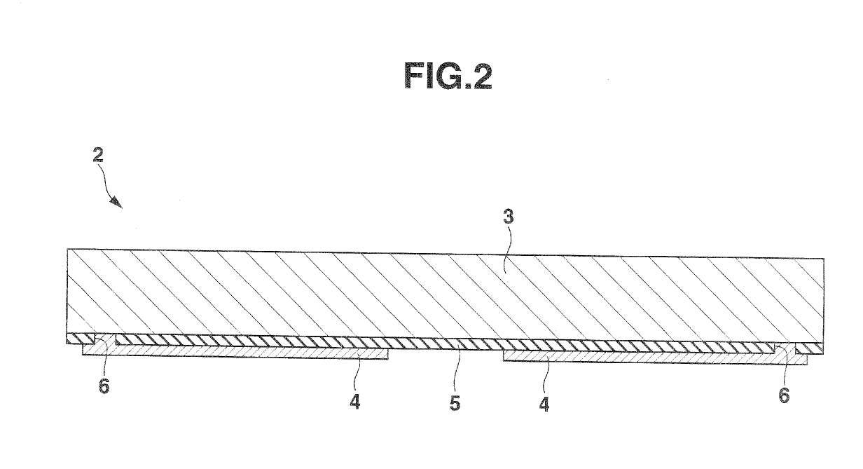

The semiconductor construct 2 before sealed is as shown in one of FIG. 2 to FIG. 4.

As shown in the sectional view of FIG. 2, the semiconductor element 3 is packaged by a so-called chip size package (CSP). That is, an insulating film 5 serving as a package is formed on the lower surface of the semiconductor element 3, and a plurality of via holes 6 corresponding to the connection pads are formed in the insulating film 5. The electrodes 4 are provided to be embedded on one end in the via holes 6 and thus serve as rewiring layers connected to the connection pads. The other ends of the electrodes 4 are connection terminals, and are arranged lengthwise and breadthwise in matrix form on the entire surface of the insulating film 5. The insulating film 5 is an inorganic insulating layer (e.g., a silicon oxide layer or silicon nitride layer), a resin insulating layer (e.g., a polyimide resin layer), or a stack of these layers. When the insulating film 5 is the stack, the inorganic insulating layer may be formed on the lower surface of the semiconductor element 3, and the resin insulating layer may be formed on the surface of the inorganic insulating layer, or vice versa.

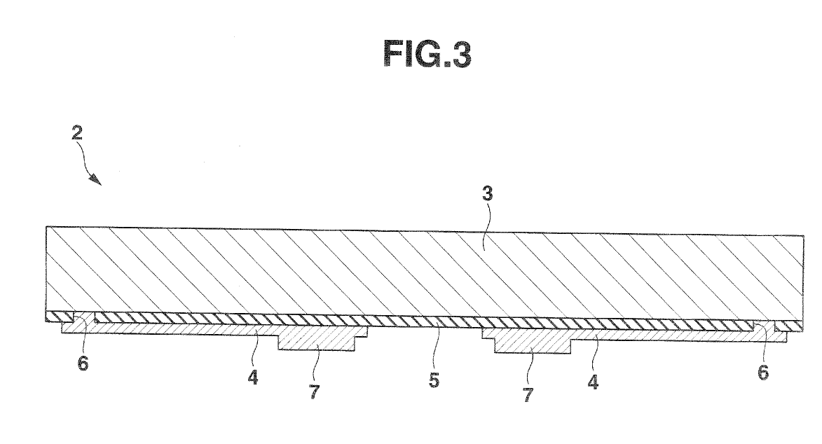

In the example of FIG. 3, a columnar post 7 is further provided on the electrode 4 of FIG. 2 in a projecting manner. The post 7 contains Cu.

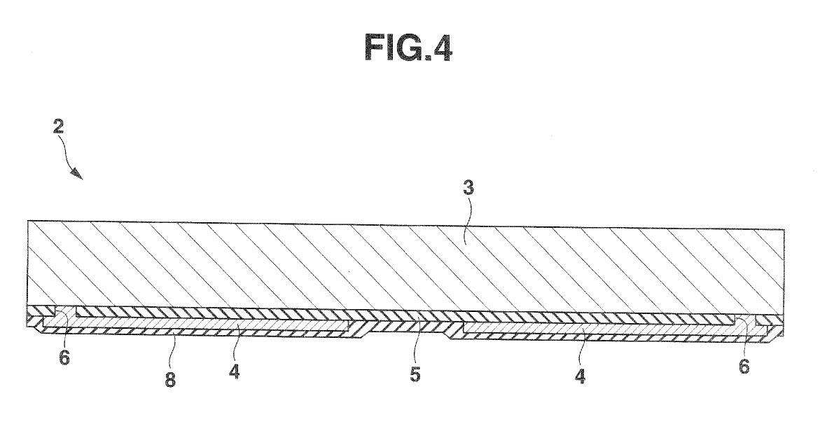

In the example of FIG. 4, a cover coat 8 covering the electrodes 4 and the insulating film 5 of FIG. 2 is formed. When the post 7 is formed as in FIG. 3, the electrodes 4 and the insulating film 5 may be covered with the cover coat 8 as in FIG. 4. In this case, the projecting surface of the post 7 may be or may not be covered with the cover coat 8.

In addition, the semiconductor construct 2 may be a bare chip which is provided not with the electrodes 4 so that the connection pads are bare.

As shown in FIG. 1, the semiconductor element 3 is sealed with an insulating sealing layer 9. The sealing layer 9 wraps the semiconductor element 3. The sealing layer 9 contains an epoxy resin, a polyimide resin or some other insulating resin. The sealing layer 9 preferably contains a thermosetting resin (e.g., an epoxy resin) having a filler therein. Although the sealing layer 9 is not fiber-reinforced like an insulating resin using glass fabric as a base material, the sealing layer 9 may contain a fiber-reinforced resin.

The sealing layer 9 is held between a insulating film 10 and an insulating film (a first insulating layer) 11. The insulating film 10 is provided on the upper surface of a sealing film. The insulating film 11 is provided on the lower surface of the sealing film. The insulating film 10 and the insulating film 11 are fiber-reinforced resin films. Specifically, the insulating film 10 and the insulating film 11 contain an epoxy resin using glass fabric as a base material, a polyimide resin using glass fabric as a base material, or some other insulating resin composite material using glass fabric as a base material. The material of the insulating film 10 is preferably the same as the material of the insulating film 11. The insulating film 10 and the insulating film 11 can contain a reinforced film except for a glass fiber.

The semiconductor element 3 is mounted on the center of the insulating film 11 so that the lower surface of the semiconductor element 3 is directed toward the insulating film 11. The lower surface of the semiconductor element 3 and the electrode 4 are bonded to the insulating film 11 by an adhesive layer 13. The semiconductor element 3 is sealed with the sealing layer 9 so that the semiconductor element 3 is bonded to the insulating film 11. The adhesive layer 13 is insulative, and contains a thermosetting resin such as an epoxy resin. The adhesive layer 13 is not fiber-reinforced.

A via hole (a second via hole) 14 is formed in the part of the adhesive layer 13 overlapping the other end of the electrode 4. A via hole (a first via hole) 12 is formed in the part of the insulating film 11 overlapping the other end of the electrode 4. Thus, the via hole 12 and the via hole 14 are in communication with each other. The via hole 14 is smaller in depth than the via hole 12. The via hole 14 is formed by applying laser light from a laser to the adhesive layer 13 through the via hole 12 which has already been formed before the formation of the via hole 14.

A plurality of through-holes 19 are formed in the sealing layer 9, the insulating film 10 and the insulating film 11. The through-holes 19 penetrate the insulating film 10, the sealing layer 9 and the insulating film 11 continuously from the surface (surface opposite to the interface with the sealing layer 9) of the insulating film 10 to the surface (surface opposite to the interface with the sealing layer 9) of the insulating film 11.

Furthermore, a lower wiring line 15 is formed on the surface (surface opposite to the interface with the sealing layer 9) of the insulating film 11. An upper wiring line 17 and a shield-ground layer 54 are formed on the surface (surface opposite to the interface with the sealing layer 9) of the insulating film 10. The shield-ground layer 54 is formed for shielding the semiconductor element 3 and protecting the semiconductor element 3 against external noise. The lower wiring line 15 is provided with a contact pad 16, and the upper wiring line 17 is provided with a contact pad 18. A vertical conduction portion 20 is formed in the through-hole 19. Specifically, the vertical conduction portion 20 is cylindrically provided on the inner wall surface of the through-hole 19, and conducts at least part of the lower wiring line 15 and the upper wiring line 17. The lower wiring line 15, the upper wiring line 17 and the vertical conduction portion 20 contain copper, nickel, or a stack of copper and nickel. In addition, the lower wiring line 15, the upper wiring line 17 and the vertical conduction portion 20 may contain some other metal.

Furthermore, the lower wiring line 15 except for the contact pad 16 and the insulating film 11 are covered with a lower overcoat layer 21. The upper wiring line 17 except for the contact pad 18 and the insulating film 10 are covered with an upper overcoat layer 23. The hollow portion of the vertical conduction portion 20 is filled with an insulating filler 25. The lower overcoat layer 21, the upper overcoat layer 23 and the filler 25 are formed by the same insulating resin material.

The lower overcoat layer 21 and the upper overcoat layer 23 function as solder resists. An opening 22 is formed in the part of the lower overcoat layer 21 corresponding to the contact pad 16 of the lower wiring line 15. A solder bump 26 is formed in the opening 22, and the solder bump 26 is thus connected to the contact pad 16. On the other hand, an opening 24 is formed in the part of the upper overcoat layer 23 corresponding to the contact pad 18 of the upper wiring line 17. In addition, the surfaces of the contact pads 16, 18 may be plated in the openings 22, 24 (e.g., single plating including gold plating, or double plating including nickel plating or gold plating), and the solder bump 26 may be formed on the contact pad 16 via the plating.

In this semiconductor device 1, the semiconductor construct 2 is mounted on the insulating film 11. However, the semiconductor construct 2 is held not by the insulating film 11 alone but by all of the sealing layer 9, the insulating film 10 and the insulating film 11. Thus, the insulating film 11 can be thin, so that the semiconductor device 1 can be reduced in thickness.

The via hole 14 that exposes the electrode 4 of the semiconductor construct 2 can be formed separately from the formation of the via hole 12. Moreover, the adhesive layer 13 is not fiber-reinforced. The via hole 14 of the adhesive layer 13 can be formed using low-output laser light such as ultraviolet laser light (UV laser light). This can inhibit heat conduction to the semiconductor construct 2.

Furthermore, the insulating film 11 is fiber-reinforced by the glass fabric base material, and therefore does not disappear due to low-output laser light such as the ultraviolet laser light. Therefore, using the insulating film 11 as a mask, the via hole 14 can be formed to self-align with the via hole 12 provided in. the insulating film 11. As a result, there is no need to separately form a resist mask by photolithography to form the via hole 14.

A method of manufacturing the semiconductor device 1 is described.

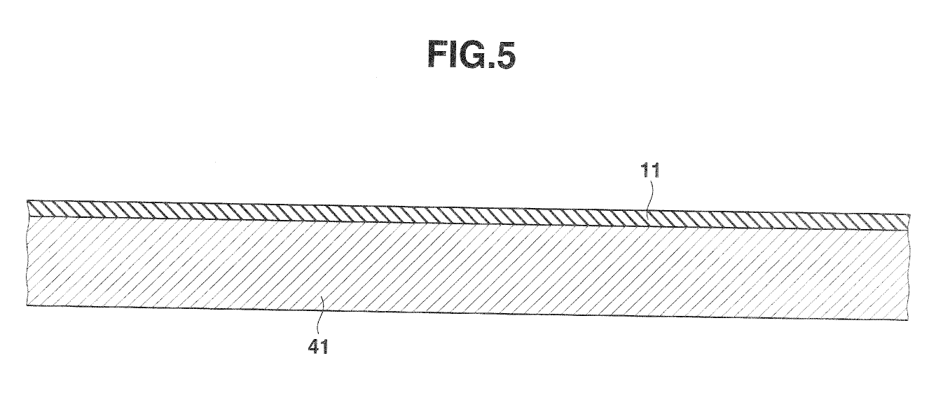

First, as shown in FIG. 5, a insulating film 11 containing a fiber-reinforced resin (e.g., an epoxy resin using glass fabric as a base material, or a polyimide resin using glass fabric as a base material) is formed on a first base material 41 for carrying a semiconductor construct 2 during the manufacturing process. The base material 41 is a carrier for facilitating the handling of the insulating film 11, and is, specifically, a metal plate of, for example, copper. The size of the base material 41 and insulating film 11 thus prepared is equal to the size of a plurality of semiconductor devices 1 shown in FIG. 1. Although FIG. 5 to FIG. 15 representatively show one semiconductor device 1, the drawings in FIG. 5 to FIG. 15 actually concern a process of manufacturing a plurality of semiconductor devices 1 that are laterally arranged in a continuous manner.

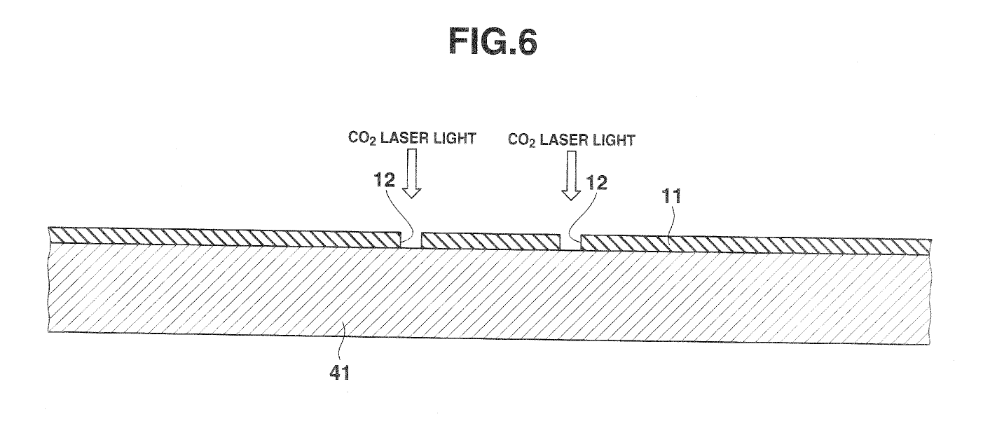

Then, as shown in FIG. 6, laser light is applied to the insulating film 11 from a laser, and a plurality of via holes 12 are formed in the insulating film 11. As the insulating film 11 contains the fiber-reinforced resin, it is preferable to use a relatively high-output carbon dioxide laser (CO₂ laser).

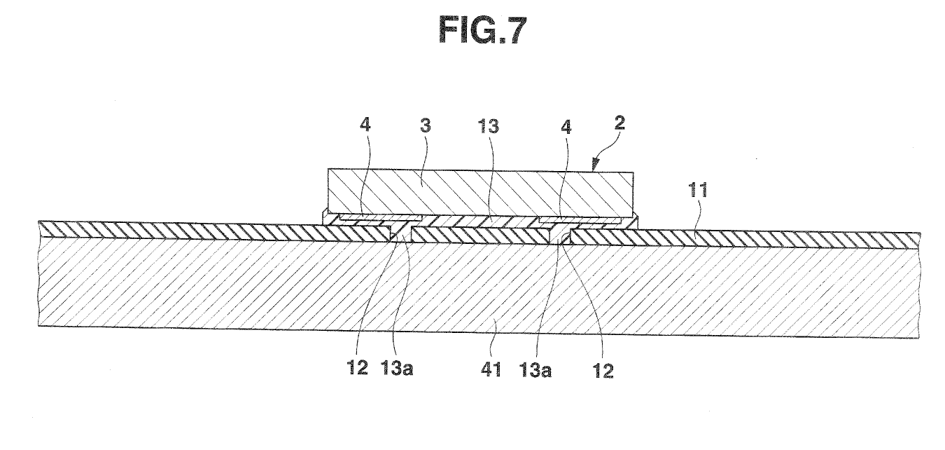

Then, as shown in FIG. 7, the semiconductor element 3 is mounted on the insulating film 11 by a facedown mounting method. Specifically, a non-conductive paste (NCP) is applied to the via hole 12 and its peripheral portion (mounting region) by a printing method or dispenser method. Alternatively, a non-conductive film (NCF) is supplied in advance to the via hole 12 and onto its peripheral portion. Then, the lower surface of the semiconductor element 3 is directed toward the non-conductive paste or the non-conductive film to align the other ends of the electrodes 4 with the via holes 12. Thus, the semiconductor element 3 is faced down on the non-conductive paste or the non-conductive film, and the lower surface of the semiconductor element 3 and the electrodes 4 are bonded to the insulating film 11 by hot pressing. Part of the non-conductive paste or the non-conductive film is embedded in the via holes 12 and cures as a filler 13a, and the non-conductive paste or the non-conductive film on the insulating film 11 cures and forms the adhesive layer 13. When the semiconductor construct 2 shown in FIG. 3 is mounted, each post 7 is aligned with each via hole 12.

In the case of the non-conductive paste, the non-conductive paste is applied to the insulating film 11 and the base material 41 exposed through the via hole 12, and the non-conductive paste is cured after the semiconductor element 3 is put on the applied semiconductor element 3. Otherwise, the non-conductive paste may be applied to the entire lower surface of the semiconductor element 3 including the electrodes 4, and the applied non-conductive paste may be cured after the semiconductor element 3 is put in contact with the insulating film 11.

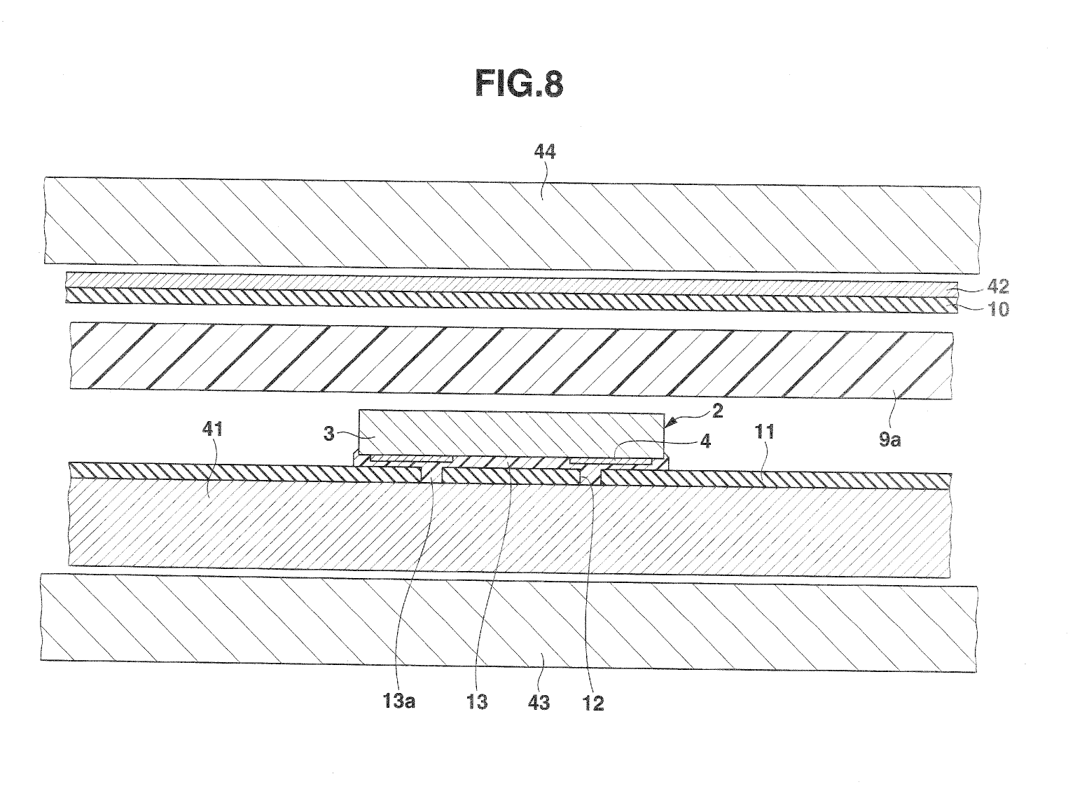

Then, as shown in FIG. 8, a second base material 42 having the insulating film (second insulating layer) 10 formed on one surface is prepared, and a thermosetting resin sheet 9a is also prepared. The second base material 42 is the same material as the first base material 41. The material of the insulating film 10 is the same as the material of the insulating film 11. The thermosetting resin sheet 9a is formed by having a filler contained in an epoxy resin, a polyimide resin or some other thermosetting resin, and semi-curing the thermosetting resin into a sheet form.

Then, the thermosetting resin sheet 9a is put on the semiconductor element 3 and the insulating film 11, and held between the insulating film 11 and the insulating film 10. These components are held between a pair of hot plates 43, 44. The first base material 41, the insulating film 11, the thermosetting resin sheet 9a, the insulating film 10 and the second base material 42 are hot-pressed by the hot plates 43, 44. The thermosetting resin sheet 9a is deformed by the hot pressing between the insulating film 10 and the insulating film 11 in accordance with the semiconductor construct 2. Further, the thermosetting resin sheet 9a is cooled off and thus cures so that the thermosetting resin sheet 9a becomes a sealing layer 9 that seals the semiconductor construct 2 and the adhesive layer 13.

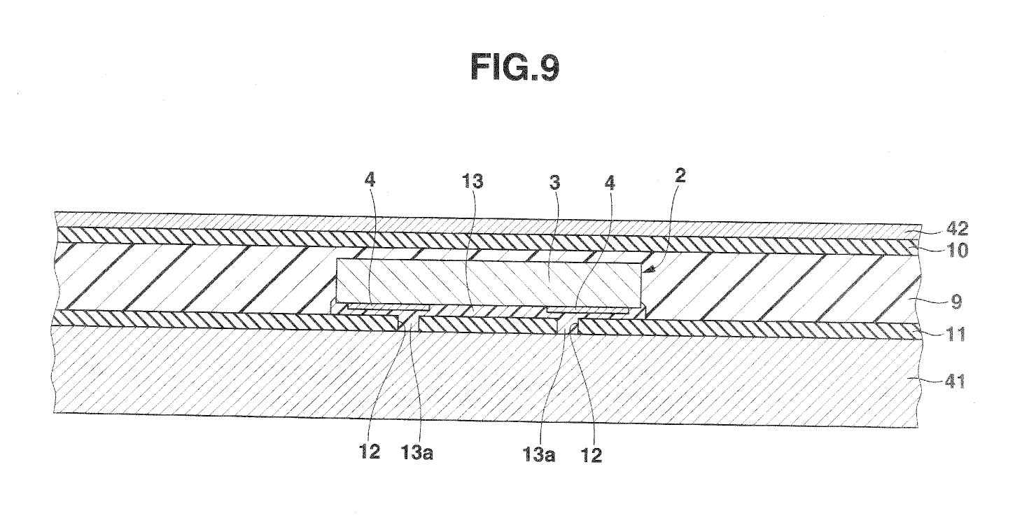

Here, as shown in FIG. 8, the insulating film 11 and the insulating film 10 that are made of the same material are disposed on both surfaces of the thermosetting resin sheet 9a, respectively. Moreover, the first base material 41 and the second base material 42 disposed on both sides are the same material and are therefore the same in the degree of thermal expansion. Thus, a stack shown in FIG. 9 does not easily warp. This makes it possible to prevent processing precision from being easily disturbed in the subsequent process.

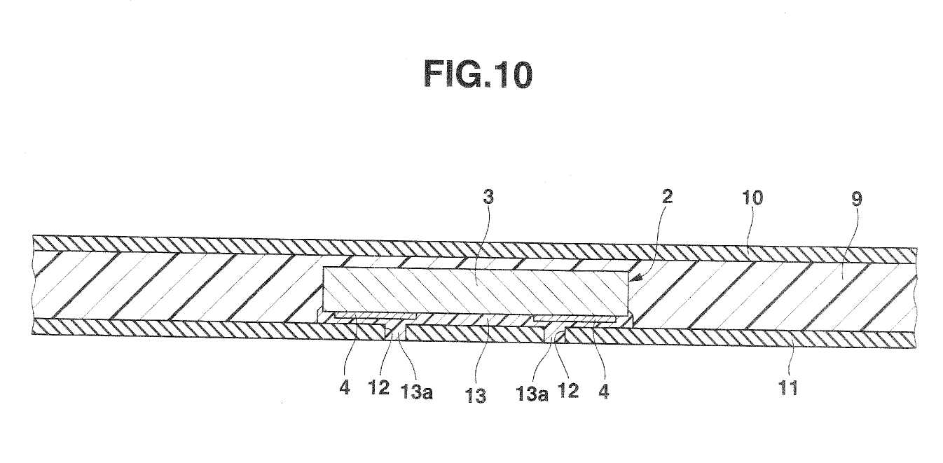

Then, as shown in FIG. 10, the first base material 41 and the second base material 42 are removed by etching (e.g., chemical etching or wet etching). The insulating film 10 and the insulating film 11 are exposed by the removal of the base materials 41, 42. The surface of the filler 13a embedded in the via hole 12 is also exposed. Here, the electrode 4 is protected by the filler 13a and is therefore not etched. Even if the base materials 41, 42 which have supported the semiconductor construct 2 during the manufacturing process are removed, sufficient strength can be ensured by the presence of the sealing layer 9, the insulating film 10 and the insulating film 11 which have been formed before the removal of the base materials. Moreover, as the base materials 41, 42 are removed, the thickness of the completed semiconductor device 1 can be small.

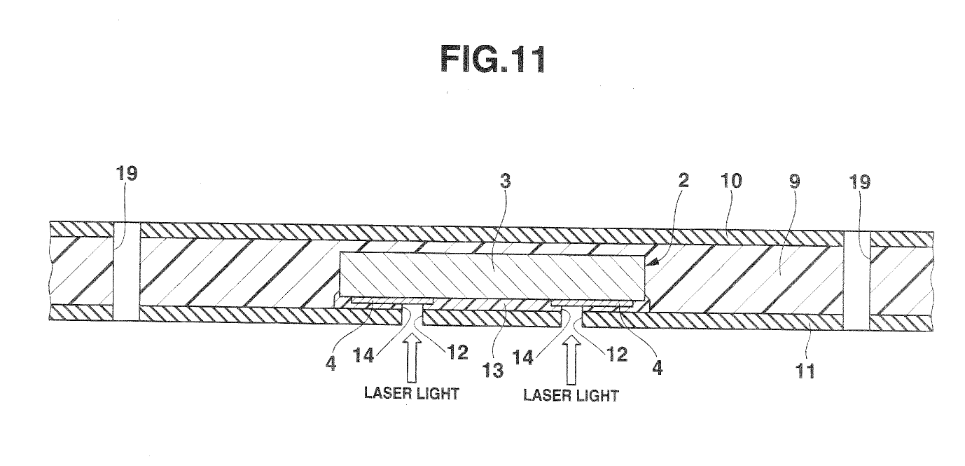

Then, as shown in FIG. 11, laser light is applied to the filler 13a within the via hole 12 from the side of the insulating film 11 opposite to the semiconductor element 3 and the electrodes 4. As a result, the filler 13a embedded in the via hole 12 disappears, and an air gap is formed in the via hole 12. Moreover, a via hole 14 which is in communication with the via hole 12 and which self-aligns with the via hole 12 is formed in the adhesive layer 13. When the via hole 14 reaches the electrode 4 and the electrode 4 is exposed in the via hole 14, the radiation of the laser light is stopped. In the case where the semiconductor construct 2 shown in FIG. 4 is mounted, the via hole 14 is formed in the adhesive layer 13 and then also formed in a cover coat 8 so that the electrode 4 is exposed.

The laser used here can be lower in intensity than the laser which has been previously used in forming the via hole 12. For example, an ultraviolet laser or low-output carbon monoxide laser (CO laser) is used to eliminate the filler 13a and to form the via hole 14. The low-output laser light can be used because the via hole 12 is previously formed in the insulating film 11 which is more resistant to laser light than the adhesive layer 13 and the filler 13a. The ultraviolet laser light is in an ultraviolet wavelength region, and the carbon monoxide laser light is not in an infrared wavelength region, so that the semiconductor element 3 can be inhibited from being thermally damaged. In addition, a portion formed by the low-output ultraviolet laser light may not be subjected to a desmear treatment described later because it is hard to cause a smear on the portion.

Furthermore, the diameter of the laser light is preferably greater than the diameter of the via hole 12. In this case, the laser light is applied to the entire inner part of the via hole 12 and to the insulating film 11 around the via hole 12. Here, the intensity of the laser used to eliminate the filler 13a and to form the via hole 14 is low. Moreover, the insulating film 11 which is fiber-reinforced and is therefore highly resistant to laser light does not disappear due to the laser light. Thus, the diameter of the via hole 12 does not increase, and the insulating film 11 functions as a mask against the laser light. In this way, the insulating film 11 functions as a mask. As a result, the via hole 14 which is in communication with the via hole 12 and which self-aligns with the via hole 12 can be formed without separately using a mask.

Still further, the via hole 14 of the adhesive layer 13 which exposes the electrode 4 of the semiconductor construct 2 can be formed separately from the formation of the via hole 12. Moreover, the adhesive layer 13 is not fiber-reinforced. Thus, the via hole 14 of the adhesive layer 13 can be formed using low-output laser light such as the ultraviolet laser light. This can inhibit heat conduction to the semiconductor construct 2.

Still further, it is possible to save the trouble of patterning the base material 41 by the photolithographic method and etching method and thereby forming an opening overlapping the via hole 12 in the base material 41 in order to use the base material 41 as a mask without removing the base material 41 that has previously been removed. Owing to the self-alignment, there is no need to adjust mask alignment for the photolithography. This allows the via hole 14 to be rapidly formed at low cost.

Further yet, the laser used to eliminate the filler 13a and to form the via hole 14 is low in intensity. This can prevent the semiconductor element 3 from being thermally damaged, especially in the case of an ultra violet laser, a desmear treatment is not needed.

Then, a through-hole 19 penetrating the insulating film 10, the sealing layer 9 and the insulating film 11 is formed by a mechanical drill or high-output CO₂ laser light. Further, the inside of the through-hole 19 and the inside of the via hole 12 are subjected to the desmear treatment.

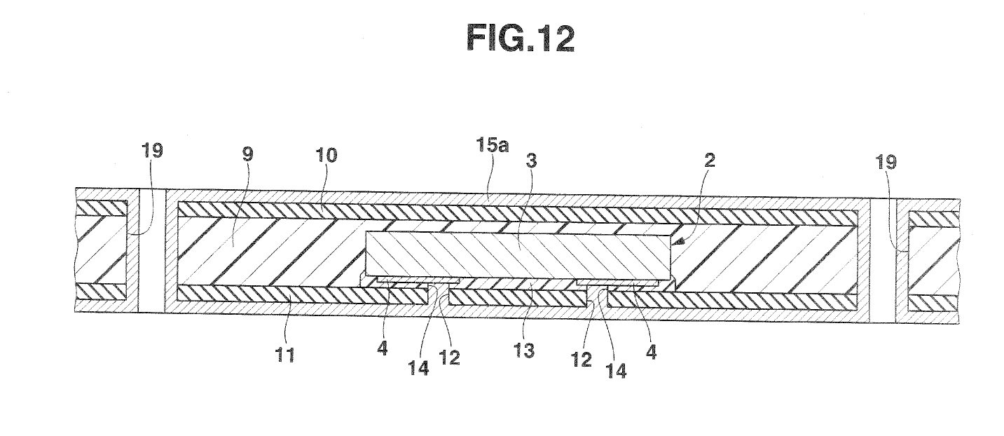

Then, as shown in FIG. 12, a metal layer 15a is formed all over the surfaces of the insulating film 10 and the insulating film 11 by electroless plating and electroplating that are conducted in order in accordance with a panel plating method. Here, part of the metal layer 15a is also formed on the inner wall surface of the through-hole 19, and part of the metal layer 15a also deposits on the electrode 4 in the via holes 14, 12, so that the via holes 14, 12 are embedded with part of the metal layer 15a.

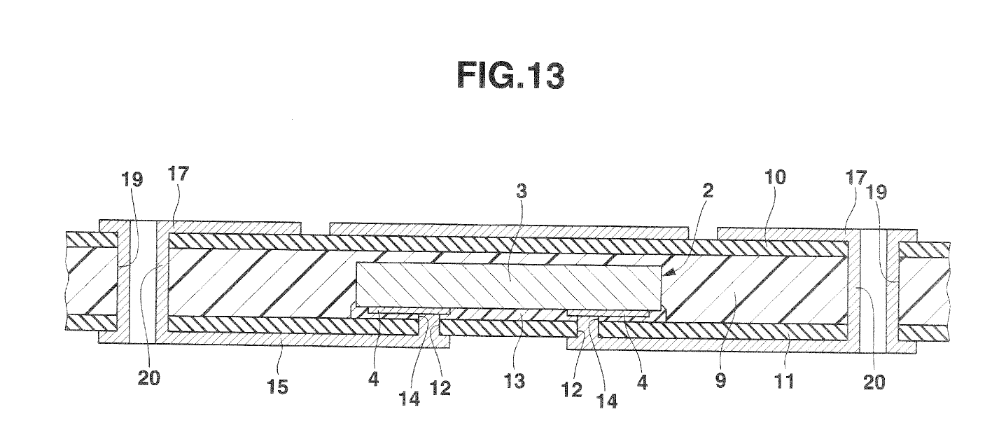

Then, as shown in FIG. 13, the metal layer 15a is patterned by the photolithographic method and etching method, thereby processing the metal layer 15a into a lower wiring line 15, an upper wiring line 17, the shield-ground layer 54 and a vertical conduction portion 20. In order to pattern the metal layer 15a, the lower wiring line 15, the upper wiring line 17 and the vertical conduction portion 20 are patterned by a subtractive process that performs etching using the photolithograph mask as described above. Alternatively, the lower wiring line 15, the upper wiring line 17 and the vertical conduction portion 20 may be patterned by a semi-additive process that forms the metal layer 15a patterned with a photolithograph mask.

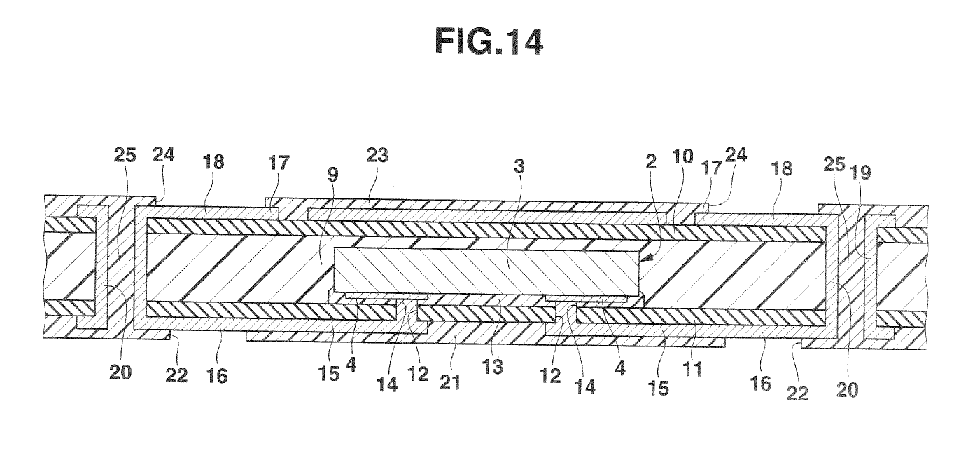

Then, as shown in FIG. 14, a resin material is printed on the surface of the insulating film 11 and on the lower wiring line 15. The resin material is then cured to pattern a lower overcoat layer 21. In similar fashion, an upper overcoat layer 23 is patterned on the surface of the insulating film 10, on the surface of the shield-ground layer 54, and on the upper wiring line 17. Further, a filler 25 is formed in the hollow portion of the vertical conduction portion 20. Openings 22, 24 are formed by the patterning of the lower overcoat layer 21 and the upper overcoat layer 23, and pads 16, 18 are exposed through the openings 22, 24.

In addition, the entire surfaces of the insulating film 11, the lower wiring line 15, the insulating film 10 and the upper wiring line 17 may be coated with a photosensitive resin by a dip coating method or spin coat method, and the hollow portion of the vertical conduction portion 20 may be filled with the photosensitive resin. Then, the coating photosensitive resin may be exposed and developed to pattern the lower overcoat layer 21, the upper overcoat layer 23 and the filler 25.

Then, gold plating, or nickel plating and gold plating is grown by electroless plating on the surfaces of the pads 16, 18 in the openings 22, 24.

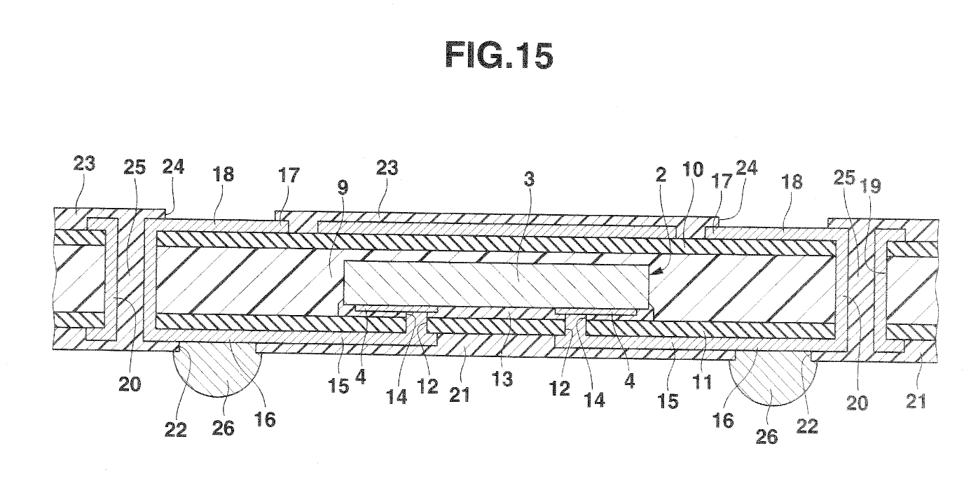

Then, as shown in FIG. 15, a solder bump 26 is formed in the opening 22.

Then, the upper overcoat layer 23, the insulating film 10, the sealing layer 9, the insulating film 11 and the lower overcoat layer 21 are cut by dicing processing to divide the continuous semiconductor devices 1 from one another as shown in FIG. 1.

As described above, according to this embodiment, the insulating film 11 and the insulating film 10 contain the fiber-reinforced resin, so that the thermosetting resin sheet 9a which is not made of a prepreg material (a material produced by impregnating hard glass fabric with a thermosetting resin) can be used (see FIG. 8). If the prepreg material that is not easily deformed is used instead of the thermosetting resin sheet 9a, an opening has to be made in the prepreg material to store the semiconductor element 3, leading to a reduced allotment for the semiconductor device. However, in this embodiment, the thermosetting resin sheet 9a is used. Therefore, no opening has to be made in the thermosetting resin sheet 9a, and the semiconductor elements 3 can be arranged on the insulating film 11 with a small pitch. This allows an increased allotment for the semiconductor device 1.

Furthermore, the via hole 12 is formed in the insulating film 11 (see FIG. 6) before the via hole 14 is formed in the adhesive layer 13 (see FIG. 11). This allows the via hole 14 to be formed using a low-intensity laser. Still more, a multi-layered structure of a residual part of the second base material 42 and the metal layer 15a can be formed as the shield-ground layer 54 by patterning the second base material 42 to leave one part of the second base material 42 (an upper part of semiconductor construct 2) without removing all of the second base material 42 after forming the sealing layer 9 between the insulating film 10 and the insulating film 11 shown in FIG. 9.

### Second Embodiment

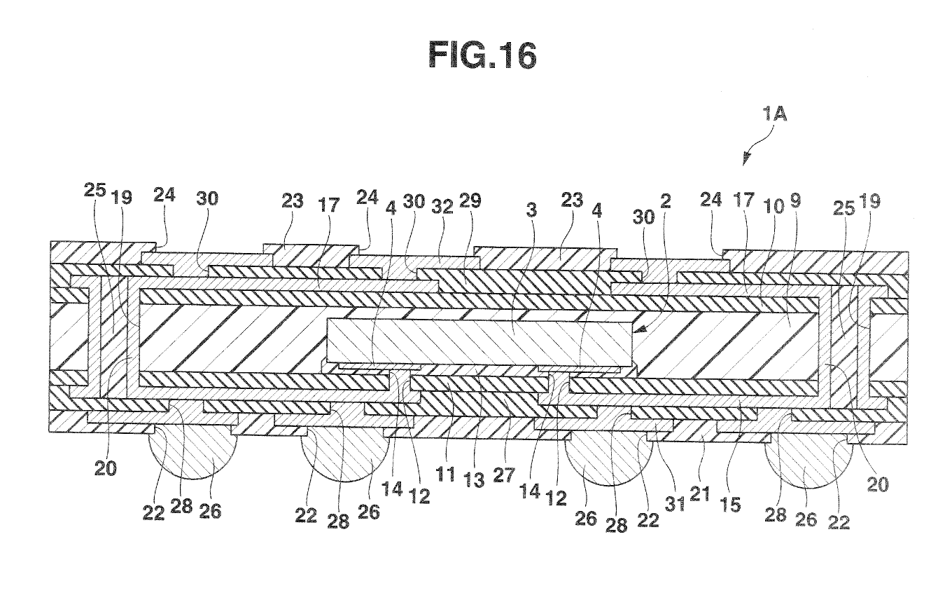

FIG. 16 is a sectional view of a semiconductor device 1A according to a second embodiment. Components in the semiconductor device 1A equivalent to those in the semiconductor device 1 according to the first embodiment are provided with the same signs.

In comparison with the semiconductor device 1, the semiconductor device 1A has increased layers due to a build-up process. That is, a second protective film 27 is provided between a lower overcoat layer 21 and a insulating film 11, and a second lower wiring line 31 is provided between the second protective film 27 and the lower overcoat layer 21. On the upper side as well, a second protective film 29 is provided between an upper overcoat layer 23 and a insulating film 10, and a second upper wiring line 32 is provided between the second protective film 29 and the upper overcoat layer 23.

A via hole 28 is formed in the second protective film 27. Part of the second lower wiring line 31 is embedded in the via hole 28. The second lower wiring line 31 is thus connected to a lower wiring line 15. Moreover, a via hole 30 is formed in the second protective film 29. Part of the second upper wiring line 32 is embedded in the via hole 30. The second upper wiring line 32 is thus connected to an upper wiring line 17.

The second protective film 27 and the second protective film 29 contain a fiber-reinforced resin. Specifically, the second protective film 27 and the second protective film 29 contain an epoxy composite material using glass fabric as a base material, a polyimide composite material using glass fabric as a base material, or some other insulating resin composite material using glass fabric as a base material. The second lower wiring line 31 and the second upper wiring line 32 contain copper, nickel, or a stack of copper and nickel. A filler 25 contains an epoxy resin, a polyimide resin or some other thermosetting resin.

Apart from what has been described above, the components in the semiconductor device 1A equivalent to those in the semiconductor device 1 according to the first embodiment are provided in similar fashion.

A method of manufacturing the semiconductor device 1A is described.

The process is similar to that in the first embodiment up to the formation of the lower wiring line 15, the upper wiring line 17 and a vertical conduction portion 20 (see FIG. 5 to FIG. 13).

After the formation of the lower wiring line 15, the upper wiring line 17 and the vertical conduction portion 20, the hollow portion of the vertical conduction portion 20 is filled with a filler 25.

Then, the surface of the insulating film 10 and the upper wiring line 17 are covered with the second protective film 29. A via hole 30 is formed in the second protective film 29 by the radiation of laser light from a laser. A second upper wiring line 32 is patterned and formed. An upper overcoat layer 23 is patterned and formed.

Furthermore, the surface of the insulating film 11 and the lower wiring line 15 are covered with a second protective film 27. A via hole 28 is formed in the second protective film 27 by the radiation of laser light from the laser. A second lower wiring line 31 is patterned and formed. A lower overcoat layer 21 is patterned, and a solder bump 26 is formed in an opening 22 of the lower overcoat layer 21. Then, the continuous semiconductor devices 1A are divided from one another by dicing processing. Further, a grounded shield-ground layer 54 may intervene between the insulating film 10 and the upper overcoat layer 23 above a semiconductor construct 2.

### Third Embodiment

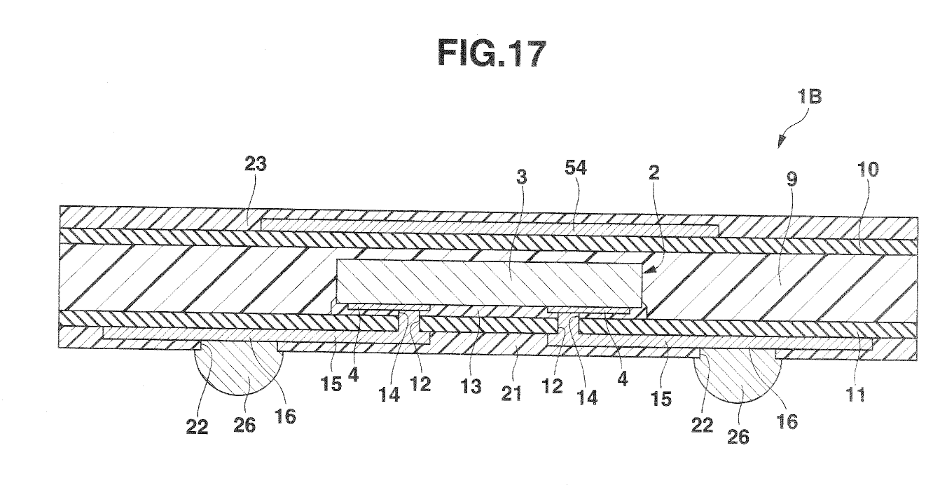

FIG. 17 is a sectional view of a semiconductor device 1B according to a third embodiment. Components in the semiconductor device 1B equivalent to those in the semiconductor device 1 according to the first embodiment are provided with the same signs.

In comparison with the semiconductor device 1, the semiconductor device 1B is not provided with the through-hole 19, the filler 25, the vertical conduction portion 20, the upper wiring line 17, the pad 18 and the opening 24. Other components are provided in the semiconductor device 1B in similar fashion to the semiconductor device 1.

In contrast with the method of manufacturing the semiconductor device 1 according to the first embodiment, a method of manufacturing the semiconductor device 1B comprises neither a step of forming the through-hole 19 nor a step of patterning the upper wiring line 17 and the vertical conduction portion 20. Moreover, in the method of manufacturing the semiconductor device 1B, an upper overcoat layer 23 is simply formed without being patterned. In other respects, the method of manufacturing the semiconductor device 1B is similar to the method of manufacturing the semiconductor device 1.

### Fourth Embodiment

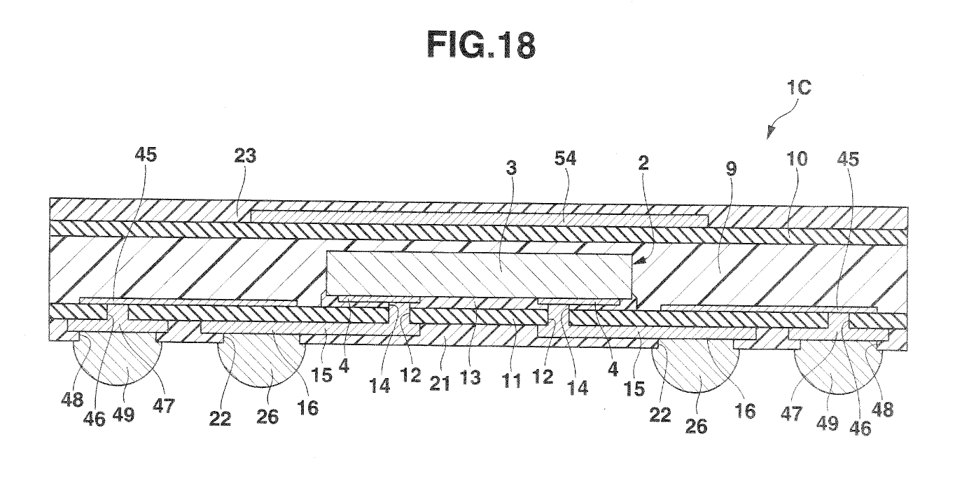

FIG. 18 is a sectional view of a semiconductor device 1C according to a fourth embodiment. Components in the semiconductor device 1C equivalent to those in the semiconductor device 1 according to the first embodiment are provided with the same signs.

In comparison with the semiconductor device 1, the semiconductor device 1C is not provided with the through-hole 19, the filler 25, the vertical conduction portion 20, the upper wiring line 17, the pad 18 and the opening 24.

Furthermore, the semiconductor device 1C has a ground wiring line. That is, a ground layer 45 is provided between a insulating film 11 and a sealing layer 9. A via hole 12 is formed in the insulating film 11. A ground wiring line 47 is provided between the insulating film 11 and a lower overcoat layer 21. Part of the ground wiring line 47 is embedded in a via hole 46 and thus connected to the ground layer 45. A opening 48 is formed in the lower overcoat layer 21. A solder bump 49 is provided in the opening 48. The solder bump 49 is connected to the ground wiring line 47. Moreover, a grounded shield-ground layer 54 intervenes between a insulating film 10 and an upper overcoat layer 23 above a semiconductor construct 2, so that a semiconductor element 3 is protected against an external light and an external noise. The shield-ground layer 54 also functions as a radiator of the semiconductor construct 2.

Other components in the semiconductor device 1B and 1C are provided in similar fashion to the semiconductor device 1.

A method of manufacturing the semiconductor device 1C is described.

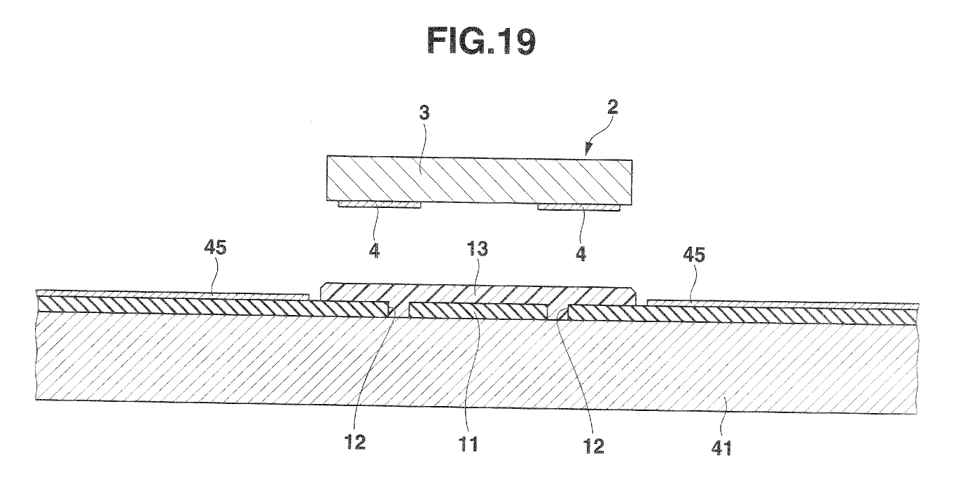

A step of forming a insulating film 11 on a first base material 41 is similar to that in the first embodiment (see FIG. 5). Further, carbon dioxide laser light is applied to the insulating film 11 to form a via hole 12 in the insulating film 11. Then, as shown in FIG. 19, a ground layer 45 is formed on the insulating film 11. Further, this method is similar to that in the first embodiment from the step of mounting the semiconductor construct 2 on the insulating film 11 to the step of eliminating a filler 13a in the via hole 12 and forming a via hole 14 in an adhesive layer 13 (see FIG. 19 and FIG. 7 to FIG. 11). Further, carbon dioxide laser light is applied to the lower surface of the insulating film 11 to form a via hole 46 at a certain position in the insulating film 11 after the ground layer 45 is formed and the first base material 41 is removed. The ground layer 45 can be formed on the insulating film 11, in this case, a via hole 12 is formed in the insulating film 11 after the ground layer 45 is formed. And the via hole 46 can be formed by using a UV laser light, in this case, the via hole 12 and the via hole 46 can be formed simultaneously at the step shown in FIG. 6 after the ground layer 45 is formed. In all cases, the via hole 46 is formed after the ground layer 45 is formed.

A lower wiring line 15 and a ground wiring line 47 are patterned without carrying out the step of forming a through-hole 19 as in the first embodiment after the via hole 14 is formed.

Then, an upper overcoat layer 23 is simply formed, but the upper overcoat layer 23 is not patterned. On the other hand, a lower overcoat layer 21 is patterned to form an opening 22 and an opening 48 in the lower overcoat layer 21. Thus, the lower wiring line 15 is exposed in the opening 22, and the ground wiring line 47 is exposed in the opening 48.

Then, a solder bump 26 is formed in the opening 22 of the lower overcoat layer 21, and a solder bump 49 is formed in the opening 48.

Then, the continuous semiconductor devices 1C are divided from one another by dicing processing.

### Fifth Embodiment

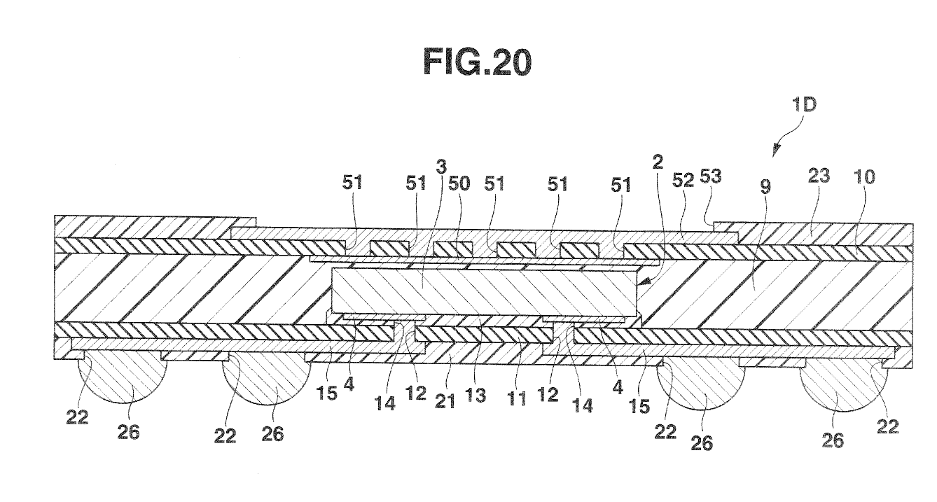

FIG. 20 is a sectional view of a semiconductor device 1D according to a fifth embodiment. Components in the semiconductor device 1D equivalent to those in the semiconductor device 1 according to the first embodiment are provided with the same signs.

In comparison with the semiconductor device 1, the semiconductor device 1D is not provided with the through-hole 19, the filler 25, the vertical conduction portion 20, the upper wiring line 17, the pad 18 and the opening 24.

Furthermore, in comparison with the semiconductor device 1, the semiconductor device 1D has a structure with high heat radiation performance. That is, a heat transmitting film 50 is provided between a insulating film 10 and a sealing layer 9 above a semiconductor element 3. A plurality of via holes 51 are formed in the insulating film 10. A film-like heat sink 52 is formed on the insulating film 10. Part of the heat sink 52 is embedded in the via hole 51 and is thus in contact with the heat transmitting film 50. An opening 53 is formed in the upper overcoat layer 23. The heat sink 52 is exposed in the opening 53. The heat transmitting film 50 and the heat sink 52 contain copper or some other metal material. The heat of a semiconductor construct 2 is radiated by the heat transmitting film 50 and the heat sink 52. Preferably, this heat sink is grounded and functions as a shield layer.

A method of manufacturing the semiconductor device 1D is described.

The process is similar to that in the first embodiment up to the step of mounting a semiconductor element 3 on a insulating film 11 (see FIG. 5 to FIG. 7).

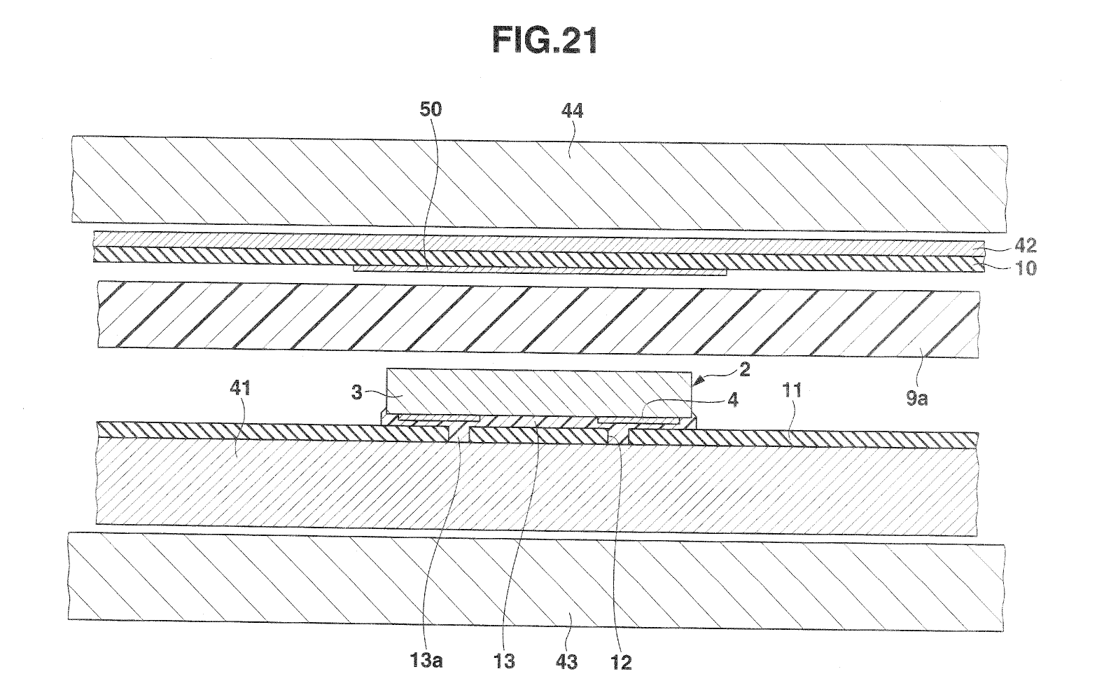

Then, a insulating film 10 formed on a second base material 42 is prepared, and a thermosetting resin sheet 9a is also prepared (FIG. 21). A heat transmitting film 50 is patterned on the lower surface of the insulating film 10 for each semiconductor element 3.

Then, the thermosetting resin sheet 9a is put on the insulating film 11 from above the semiconductor element 3. The heat transmitting film 50 is aligned with the semiconductor element 3 so that the thermosetting resin sheet 9a intervenes between the insulating film 11 and the insulating film 10. These components are hot-pressed by a pair of hot plates 43, 44.

Further, the process is similar to that in the first embodiment from the step of removing a first base material 41 and the second base material 42 to the step of eliminating a filler 13a in a via hole 12 and forming a via hole 14 in an adhesive layer 13 (see FIG. 10 to FIG. 11).

Then, the step of forming a through-hole 19 as in the first embodiment is not carried out. However, a via hole 51 is formed in the insulating film 10, and the heat transmitting film 50 is exposed in the via hole 51.

Then, a heat sink 52 is patterned. As a result, part of the heat sink 52 is embedded in the via hole 51, and the heat sink 52 is in contact with the heat transmitting film 50. Further, the upper overcoat layer 23 is patterned. An opening 53 is formed in the upper overcoat layer 23. The heat sink 52 is exposed in the opening 53.

After the patterning of a lower wiring line 15, a lower overcoat layer 21 is formed. An opening 22 is formed in the lower overcoat layer 21. The lower wiring line 15 is exposed in the opening 22. A solder bump 26 is formed in the opening 22 of the lower overcoat layer 21.

### Sixth Embodiment

The structure of a semiconductor device according to this embodiment is the same as the structure of the semiconductor device 1 according to the first embodiment. A method of manufacturing the semiconductor device according to this embodiment is different from the method of manufacturing the semiconductor device 1 according to the first embodiment.

The method of manufacturing the semiconductor device according to this embodiment is described.

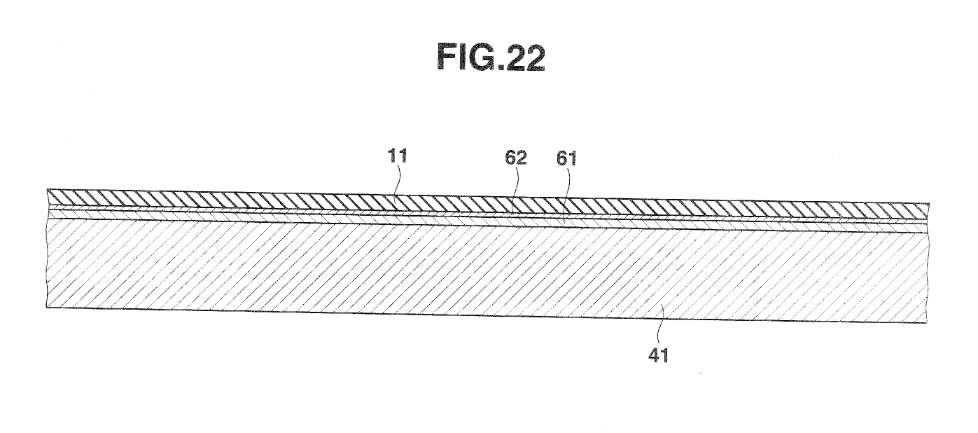

First, as shown in FIG. 22, a first metal film 61 is formed on a first base material 41, and a second metal film 62 is formed on via hole 12 is formed. Both the second metal film 62 and the first base material 41 are mainly made of copper. The first metal film 61 is mainly made of nickel. In addition, the metal films 61, 62 may contain some other metal. Moreover, the second metal film 62 does not have to be formed and only first metal film 61 can be formed. Still more, metal layers laminated on the first base material 41 can be not only two layers of metal layers 61, 62, but three layers or more.

Then, a insulating film 11 is formed on the second metal film 62. When the second metal film 62 is not formed, the insulating film 11 is formed on the first metal film 61.

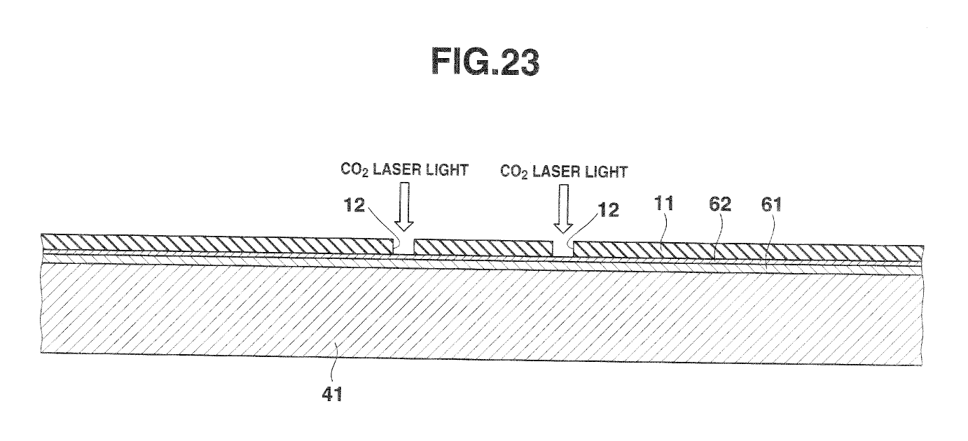

Then, as in the first embodiment, a via hole 12 is formed in the insulating film 11 by, for example, CO₂ laser light as shown in FIG. 23.

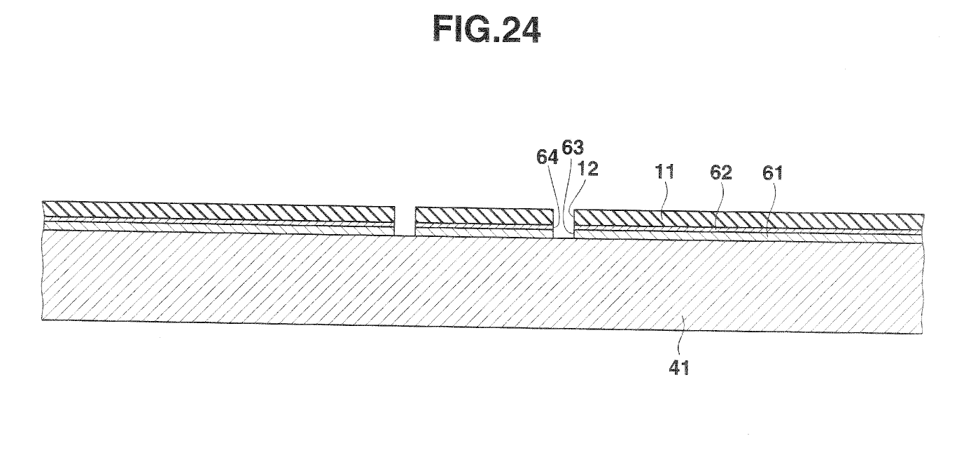

Then, as shown in FIG. 24, using the insulating film 11 as a mask, a part of the second metal film 62 located in the via hole 12 is wet-etched by a first etchant, and a part of the first metal film 61 located in the via hole 12 is wet-etched by a second etchant. Thus, an opening 64 is formed in the second metal film 62, and an opening 63 is formed in the first metal film 61. When the second metal film 62 is etched, the first metal film 61 functions as an etching stopper because the first etchant has the property of not easily etching the first metal film 61. Therefore, the second metal film 62 alone is etched, and the first base material 41 that contains copper as in the second metal film 62 is not damaged by the first etchant. When the first metal film 61 is etched, the base material 41 functions as an etching stopper because the second etchant has the property of not easily etching the second metal film 62 and the base material 41. Therefore, the first metal film 61 alone is etched, and the second metal film 62 and the base material 41 are not damaged by the second etchant. The material of the first metal film 61 is thus different from the material of the second metal film 62 and the base material 41. Therefore, by using an etchant that ensures selectivity between the material of the first metal film 61 and material of the second metal film 62, the second metal film 62 and the first base material 41 are not damaged.

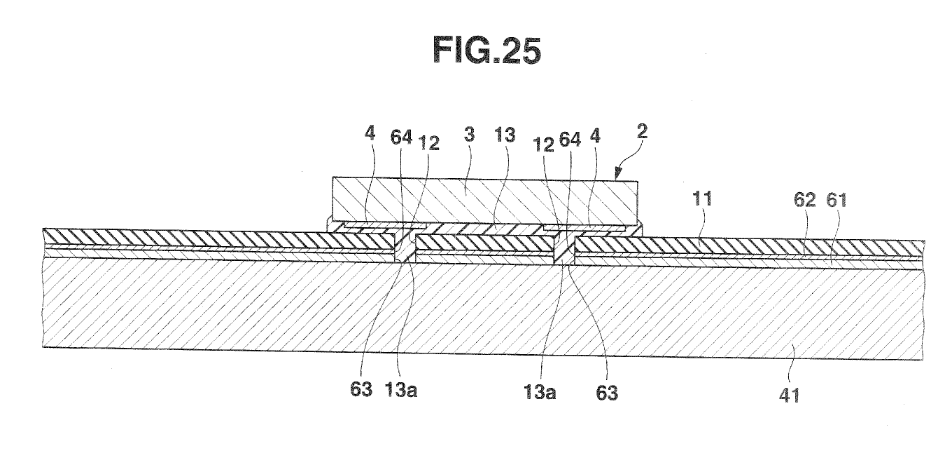

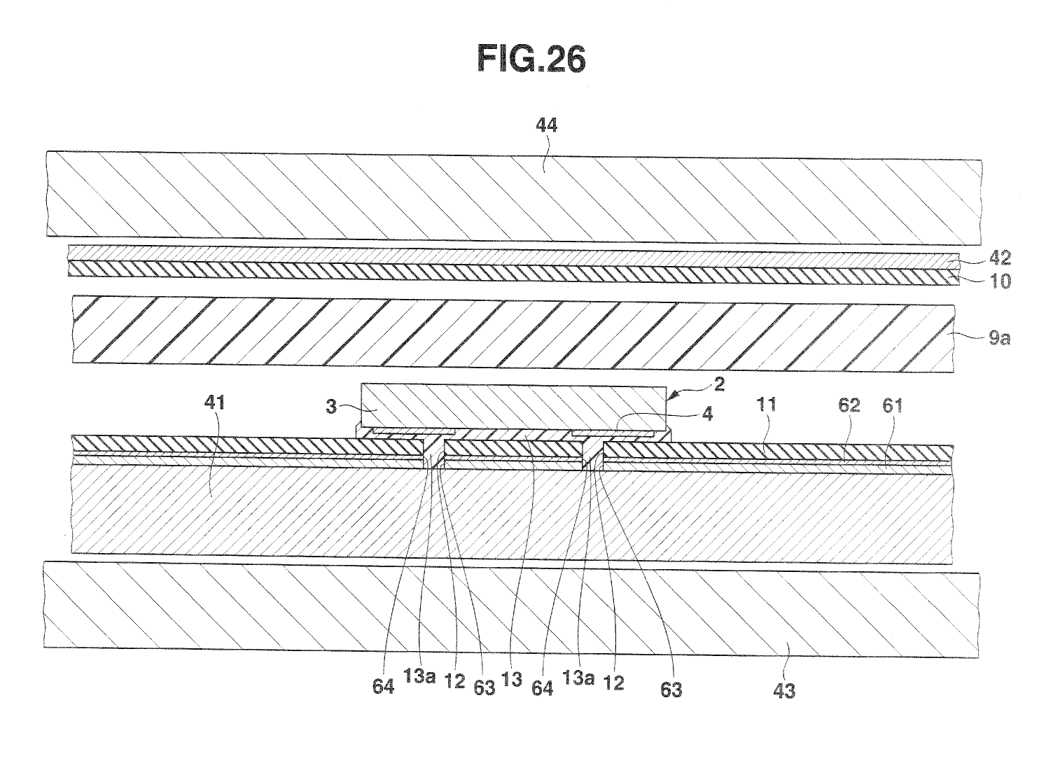

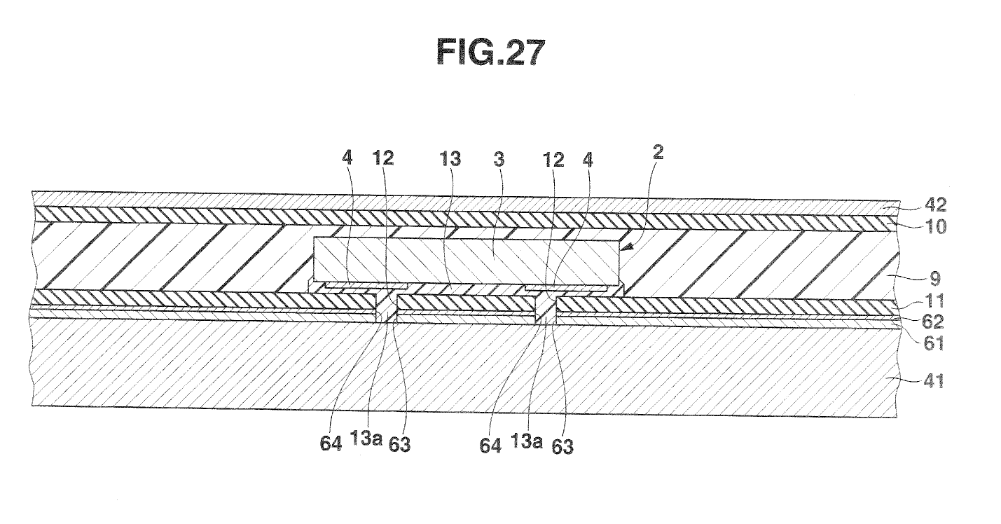

Furthermore, the process is similar to that in the first embodiment from the step of mounting a semiconductor element 3 to the step of sealing the semiconductor element 3 with a sealing layer 9 (see FIG. 25 to FIG. 27). When the semiconductor element 3 is mounted, part of a non-conductive paste or the non-conductive film is embedded in the openings 63, 64 and the via hole 12 and cures as a filler 13a.

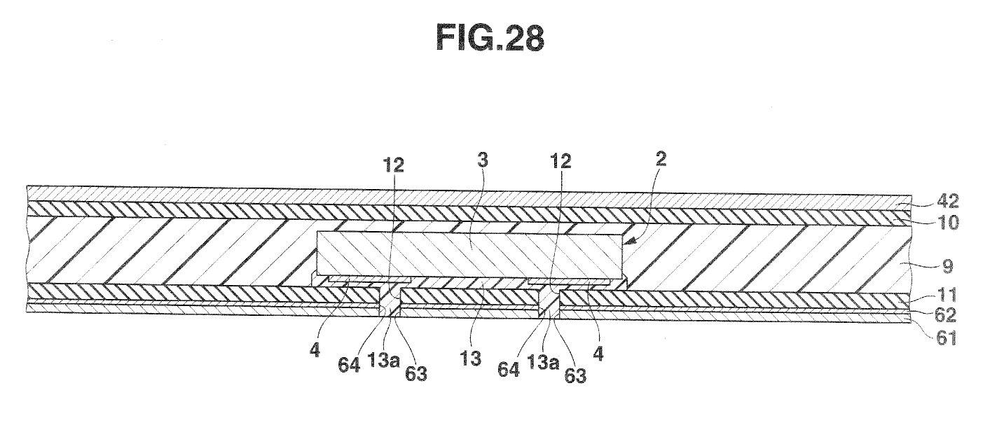

Then, as shown in FIG. 28, the base material 41 is removed by etching, but the second base material 42 is not removed.

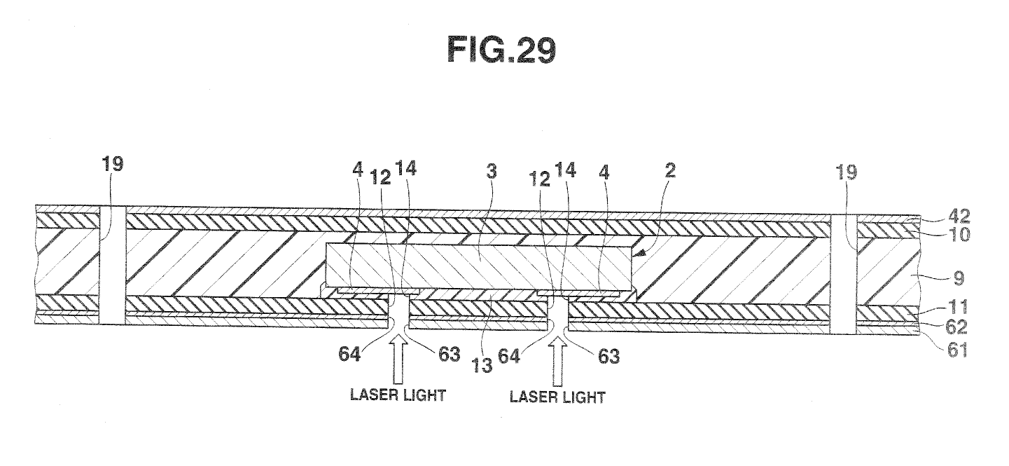

Then, as shown in FIG. 29, the filler 13a embedded in the openings 63, 64 and the via hole 12 is eliminated by ultraviolet laser light. Moreover, a via hole 14 in communication with the openings 63, 64 and the via hole 12 is formed in an adhesive layer 13. Here, as the diameter of the laser light is greater than the diameter of the openings 63, 64 and the via hole 12, the laser light is radiated to the entire inside of the openings 63, 64 and the via hole 12 and to the first metal film 61 around the opening 63. However, the first metal film 61 and the second metal film 62 function as masks. Thus, the openings 63, 64 and the via hole 12 are not expanded by the laser light. As a result, the via hole 14 which self-aligns with the openings 63, 64 and the via hole 12 before irradiated with the laser light is formed. Moreover, the insulating film 11 can be inhibited from being damaged. Since the low-output ultraviolet laser light is used, a semiconductor construct 2 can be inhibited from being thermally damaged. Further, as the via hole 12 and the openings 63, 64 are formed in advance, the via hole 14 can be formed by the low-intensity laser light.

Then, a through-hole 19 is extended from the surface of the second base material 42 to the surface of the insulating film 11 by a mechanical drill or laser light.

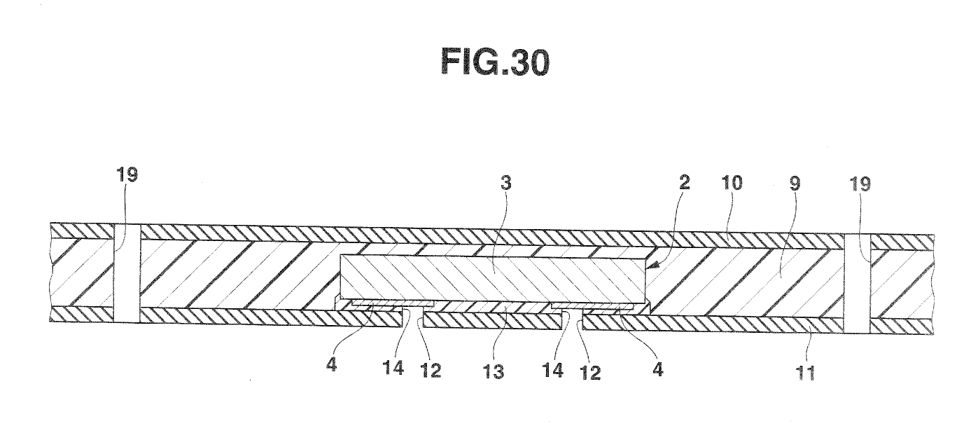

Then, as shown in FIG. 30, the second base material 42, the first metal film 61 and the second metal film 62 are removed by etching. In addition, the step of removing the first metal film 61 by etching may be performed before the step of forming the via hole 14 by laser light and after the removal of the base material 41 by etching.

Furthermore, the process is similar to that in the first embodiment from the step of patterning a lower wiring line 15, an upper wiring line 17 and a vertical conduction portion 20 to the step of dicing (see FIG. 12 to FIG. 15).

### Seventh Embodiment

The structure of a semiconductor device according to this embodiment is the same as the structure of the semiconductor device 1 according to the first and sixth embodiments. A method of manufacturing the semiconductor device according to this embodiment is different from the method of manufacturing the semiconductor device 1 according to the first and sixth embodiments.

The method of manufacturing the semiconductor device according to this embodiment is described.

The process is similar to that in the sixth embodiment from the step of forming a insulating film 11 on a second metal film 62 to the step of forming a via hole 14 and a through-hole 19 (see FIG. 22 to FIG. 29).

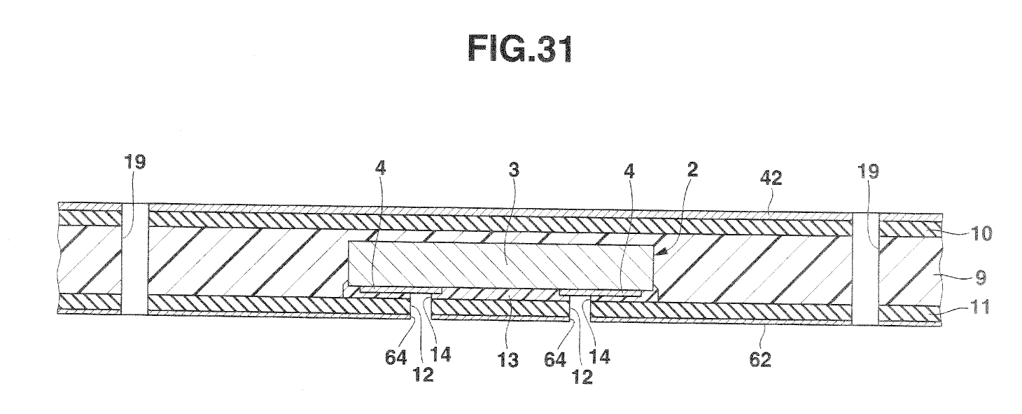

Then, as shown in FIG. 31, a first metal film 61 is removed by etching, but the second metal film 62 and a second base material 42 are left.

Then, electroplating is performed using the remaining second metal film 62 and second base material 42 as seed layers. As a result, a metal layer 15a is formed on the entire surfaces of a insulating film 10 and the insulating film 11, on the inner wall surface of the through-hole 19, and in the via holes 14, 12 (see FIG. 12). And an unnecessary portion is removed by etching with using a resist mask. The metal layer 15a is patterned by a subtractive process. Suitable patterning process can be not only the subtractive process but a semi additive process.

Then, the metal layer 15a is patterned on a lower wiring line 15, an upper wiring line 17 and a vertical conduction portion 20 by the photolithographic method and etching method (see FIG. 13).

Furthermore, the process is similar to that in the first embodiment from the step of forming an upper overcoat layer 23, a lower overcoat layer 21 and a filler 25 to the step of dicing (see FIG. 14 to FIG. 15).

### Eighth Embodiment

The structure of a semiconductor device according to this embodiment is the same as the structure of the semiconductor device according to the first, sixth and seventh embodiments. A method of manufacturing the semiconductor device according to this embodiment is different from the method of manufacturing the semiconductor device 1 according to the first, sixth and seventh embodiments.

The method of manufacturing the semiconductor device according to this embodiment is described.

The process is similar to that in the sixth embodiment from the step of forming a insulating film 11 on a second metal film 62 to the step of forming a via hole 14 and a through-hole 19 (see FIG. 22 to FIG. 27). However, the performance of adhesion of the second metal film 62 and the first metal film 61 is low, and the first metal film 61 and a first base material 41 are detachable from the second metal film 62.

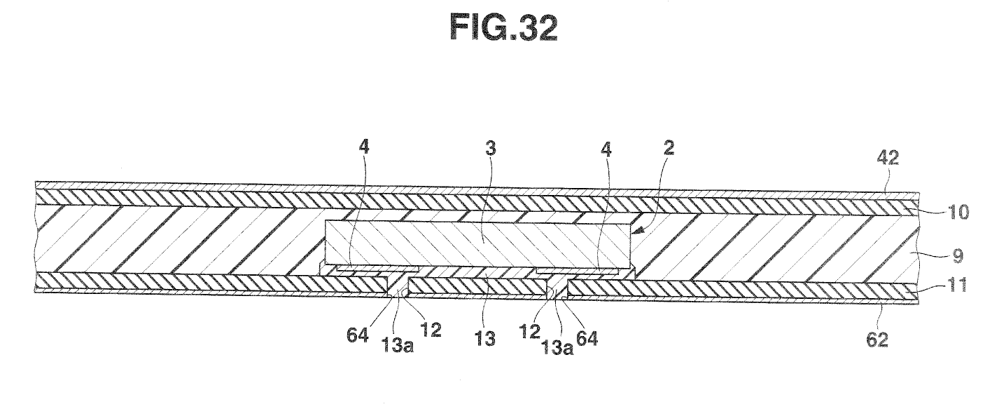

Then, as shown in FIG. 32, the first metal film 61 and the base material 41 are mechanically detached from the second metal film 62.

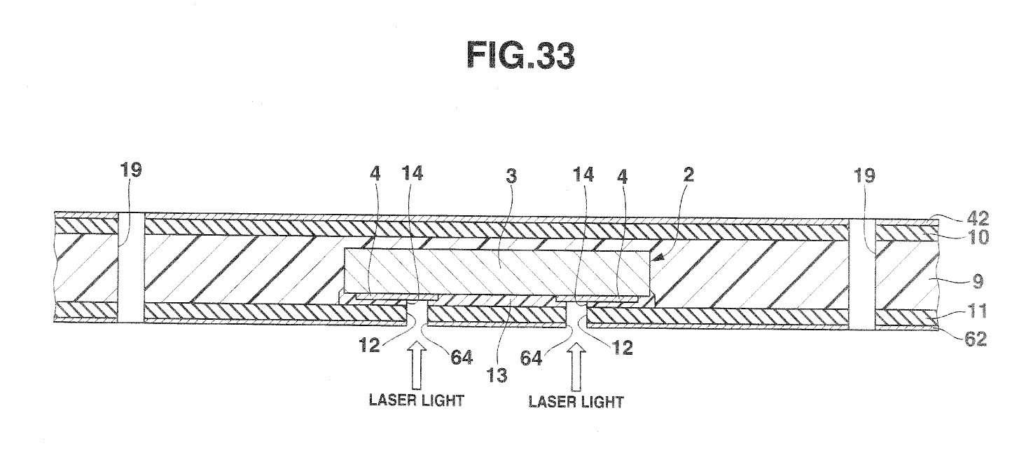

Then, as shown in FIG. 33, a filler 13a embedded in a via hole 12 and an opening 64 is eliminated by ultraviolet laser light, and the via hole 14 in communication with the via hole 12 and the opening 64 is formed in an adhesive layer 13. Here, as the diameter of the laser light is greater than the diameter of the via hole 12, the laser light is radiated to the entire inside of the via hole 12 and to the insulating film 11 around the via hole 12. However, the second metal film 62 functions as a mask. Thus, the via hole 12 is not expanded by the laser light. As a result, the via hole 14 which self-aligns with the via hole 12 before irradiated with the laser light is formed. Moreover, the insulating film 11 can be inhibited from being damaged. Further, the via hole 12 is formed in advance, and the second metal film 62 and the insulating film 11 function as masks, so that the intensity of the laser light can be low.

Then, a through-hole 19 is extended from the surface of a second base material 42 to the surface of the second metal film 62 by a mechanical drill or laser light.

Furthermore, the process is similar to that in the seventh embodiment from the step of growing a metal layer 15a using the second metal film 62 and the second base material 42 as seed layers to the step of dicing.

While various exemplary embodiments have been shown and described, the present invention is not limited to the embodiments described above. Therefore, the scope of the invention is not exclusively limited by the claims.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device manufacturing method comprising:
bonding a semiconductor element onto one surface of a first protective film via an adhesive layer, an electrode being formed in the semiconductor element, the first protective film being disposed on a first base material and including a first via hole;
removing the first base material from the first protective film;
applying first laser light to the adhesive layer through the first via hole to form a second via hole in the adhesive layer so that the electrode is exposed through the adhesive layer; and
forming a metal layer in the second via hole to connect the metal layer to the electrode.

2. The manufacturing method according to claim 1, wherein the diameter of the first laser light is greater than the diameter of the first via hole, and the second via hole is formed using the first protective film as a mask.

3. The manufacturing method according to claim 1, wherein the first protective film contains a fiber-reinforced resin.

4. The manufacturing method according to claim 1, wherein the first protective film is provided with at least one or more metal layers, and the metal layer is removed after the second via hole is formed.

5. The manufacturing method according to claim 1, wherein the first laser light is ultraviolet laser light or carbon monoxide laser light.

6. The manufacturing method according to claim 1, wherein the first via hole is formed by applying second laser light to the first protective film, the second laser light being higher in intensity than the first laser light.

7. The manufacturing method according to claim 6, wherein the first via hole is formed by applying carbon dioxide laser light to the first protective film.

8. The manufacturing method according to claim 1, wherein the metal layer is formed continuously from the second via hole onto the first protective film, and the metal layer is patterned to form a wiring line connected to the electrode.

9. The manufacturing method according to claim 1, wherein the semiconductor element bonded to the first protective film is sealed with a sealing layer.

10. The manufacturing method according to claim 9, wherein the sealing layer is held between the semiconductor element bonded to the one surface of the first protective film and a second protective film disposed on a second base material, and the sealing layer is pressurized both from the side of the first base material and from the side of the second base material.

11. The manufacturing method according to claim 10, wherein the second protective film is made of the same material as the first protective film.

12. The manufacturing method according to claim 10, wherein an upper ground layer is formed on the second protective film.

13. The manufacturing method according to claim 1, wherein a lower ground layer is formed on the one surface of the first protective film around the semiconductor element.

14. The manufacturing method according to claim 10, wherein a heat sink is formed on the second protective film.

15. The manufacturing method according to claim 1, wherein a first metal layer containing a material different from that of the first base material is provided between the first protective film and the first base material,
carbon dioxide laser light is applied to the first protective film to form the first via hole in the first protective film, and
the first metal layer is etched through the first via hole using the first protective film as a mask.

16. The manufacturing method according to claim 15, wherein a second metal layer containing a material different from that of the first metal layer is provided between the first protective film and the first metal layer, and
the second metal layer is etched through the first via hole using the first protective film as a mask.

17. A semiconductor device is manufactured by the manufacturing method according to claim 1.
